(19) United States
(12) Patent Application Publication
(10) Pub. No.: US 2026/0040588 A1
(43) Pub. Date: Feb. 5, 2026

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Hsu-Tung YEN, Kaohsiung City (TW); Ling-Sung WANG, Tainan City (TW)

(21) Appl. No.: 18/793,390

(22) Filed: Aug. 2, 2024

(51) Int. Cl. H10D 1/00; H10D 1/68

(52) U.S. Cl. CPC H10D 1/042; H10D 1/716

(57) ABSTRACT

A method for forming a semiconductor device structure is provided. The method includes forming a first lower conductive line over a substrate. The method includes forming a dielectric layer over the substrate and the first lower conductive line. The method includes partially removing the dielectric layer to form a first trench, a second trench and a first hole in the dielectric layer. The first hole is under and connected to the first trench, and the first hole extends toward the first lower conductive line. The method includes forming a first upper conductive line, a second upper conductive line, and a first capacitor via structure in the first trench, the second trench and the first hole respectively. A first linewidth of the first upper conductive line is less than a second linewidth of the second upper conductive line.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1G are cross-sectional views of various stages of a process for forming a semiconductor device structure, in accordance with some embodiments.

FIG. 1A-1 is a top view of the semiconductor device structure of FIG. 1A, in accordance with some embodiments.

FIG. 1B-1 is a top view of the semiconductor device structure of FIG. 1B, in accordance with some embodiments.

FIG. 1C-1 is a top view of the semiconductor device structure of FIG. 1C, in accordance with some embodiments.

FIG. 1D-1 is a top view of the semiconductor device structure of FIG. 1D, in accordance with some embodiments.

FIG. 1E-1 is a top view of the semiconductor device structure of FIG. 1E, in accordance with some embodiments.

FIG. 1F is a cross-sectional view of the semiconductor device structure, in accordance with an embodiment.

FIG. 1G-1 is a top view of the semiconductor device structure of FIG. 1G, in accordance with some embodiments.

FIG. 1G-2 is a cross-sectional view illustrating the semiconductor device structure along a sectional line II-II′ in FIG. 1G-1, in accordance with some embodiments.

FIG. 2A is a top view of a semiconductor device structure, in accordance with some embodiments.

FIG. 2B is a cross-sectional view illustrating the semiconductor device structure along a sectional line I-I′ in FIG. 2A, in accordance with some embodiments.

FIG. 3 is a top view of a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

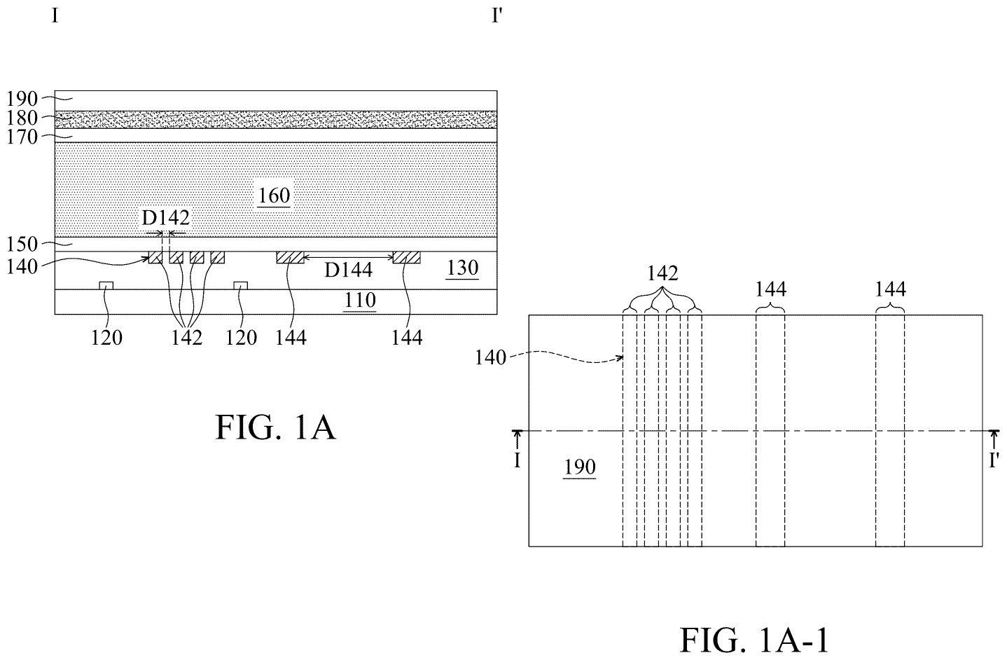

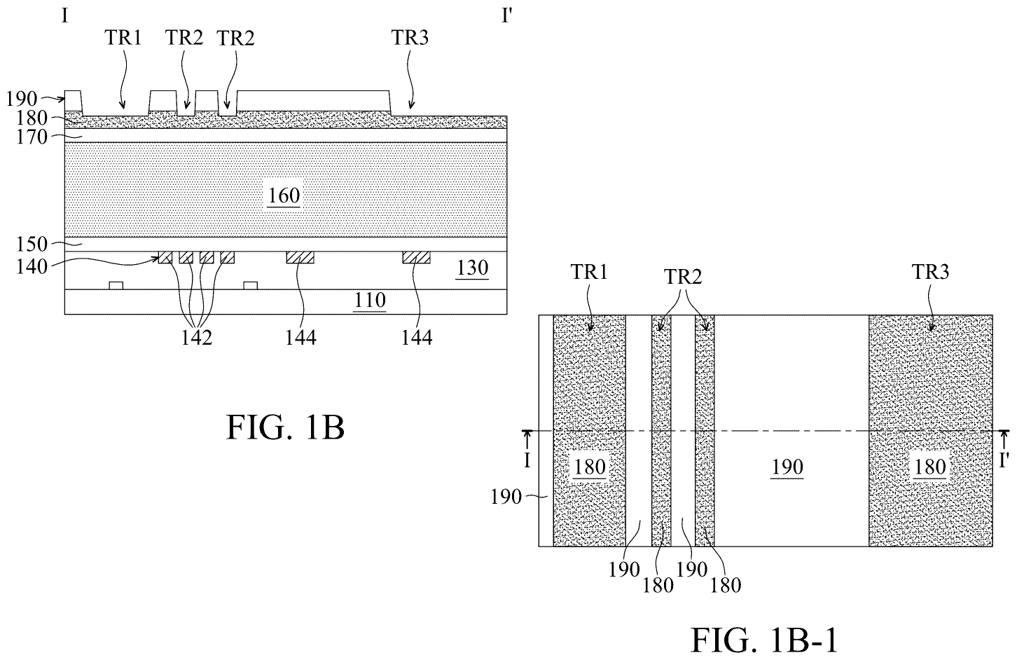

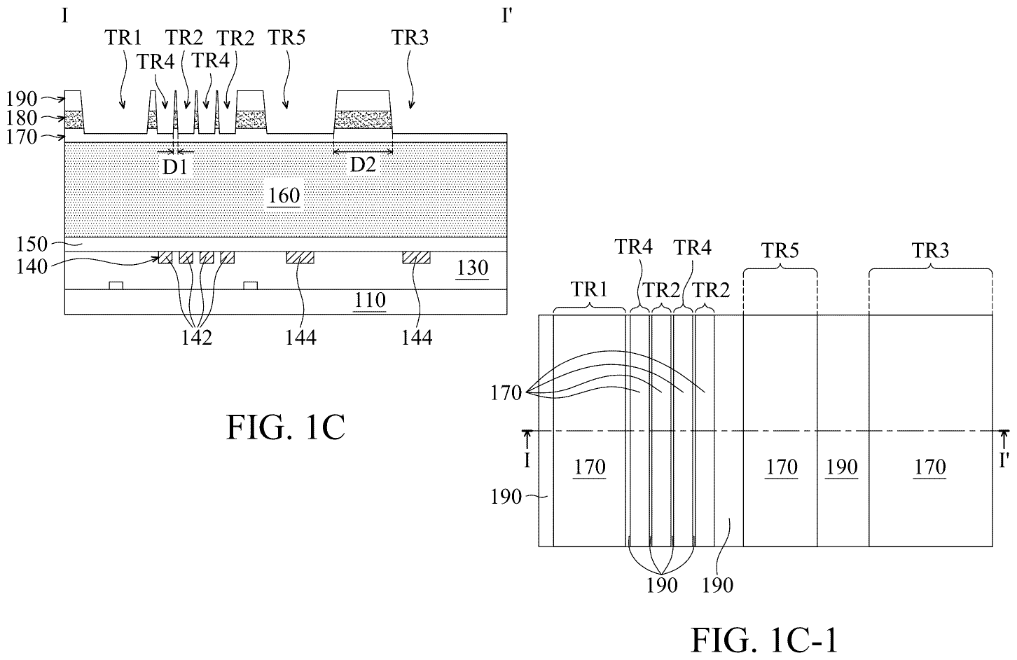

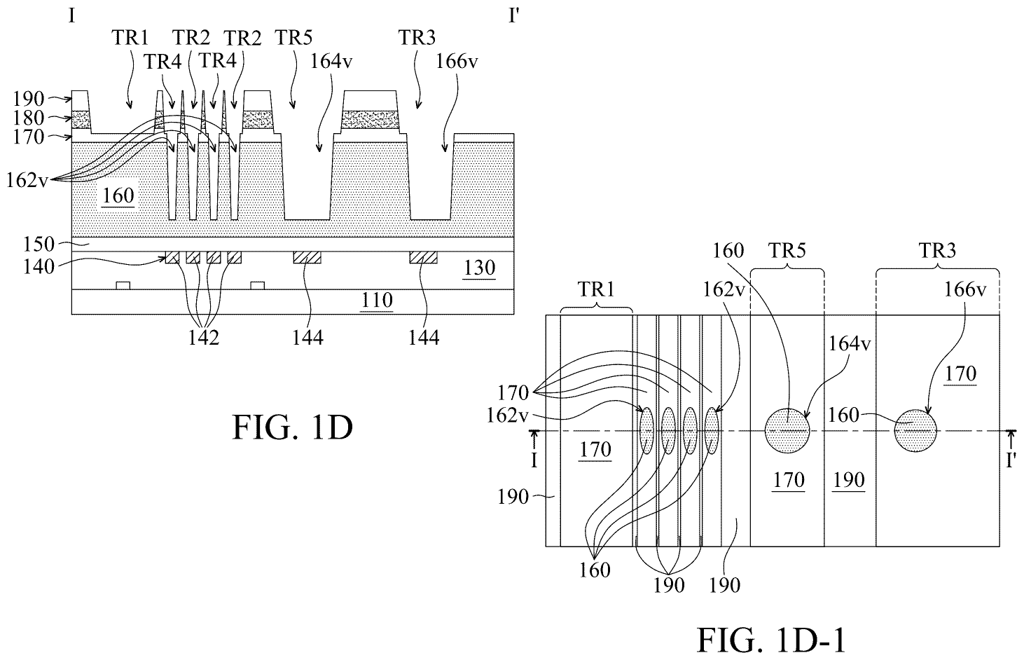

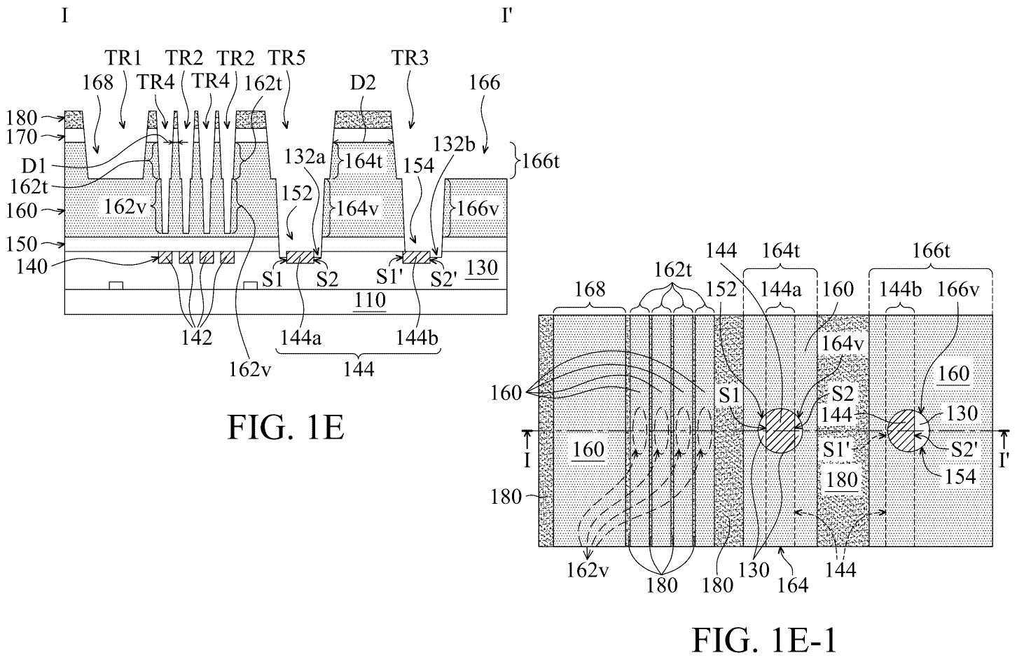

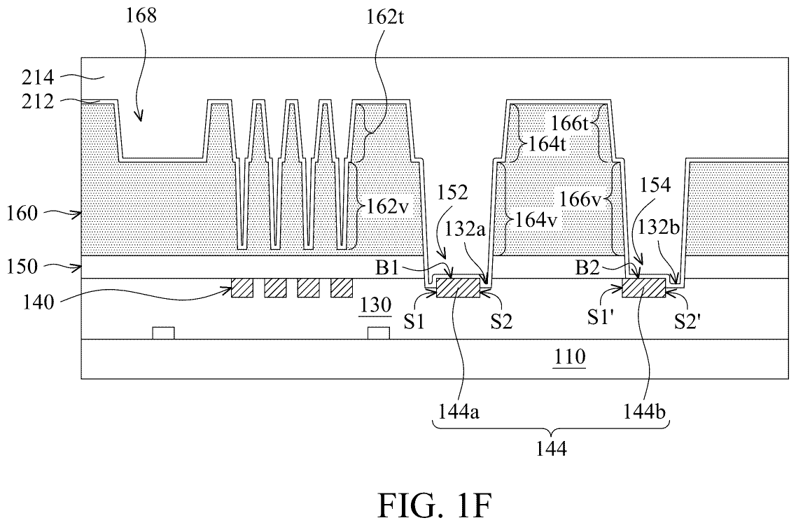

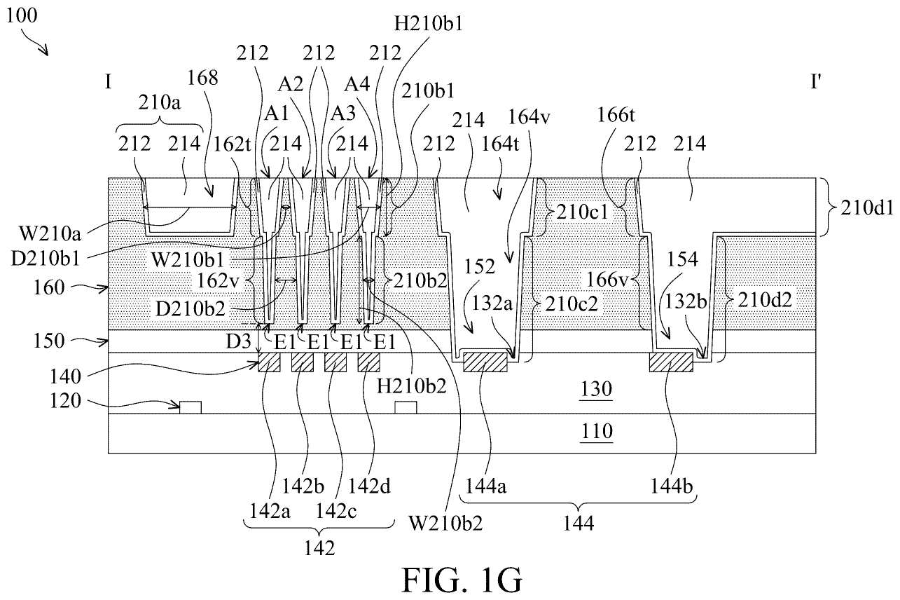

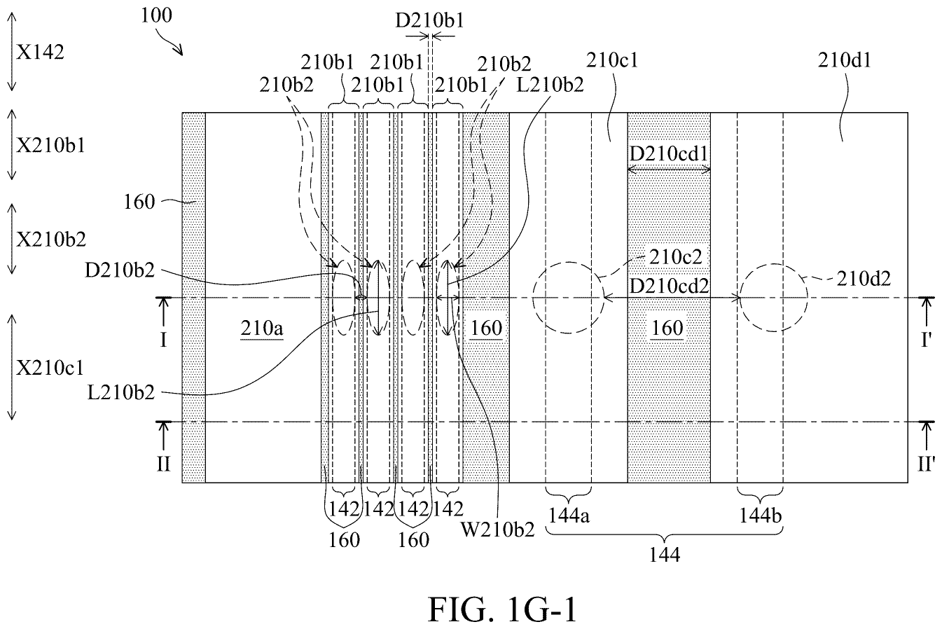

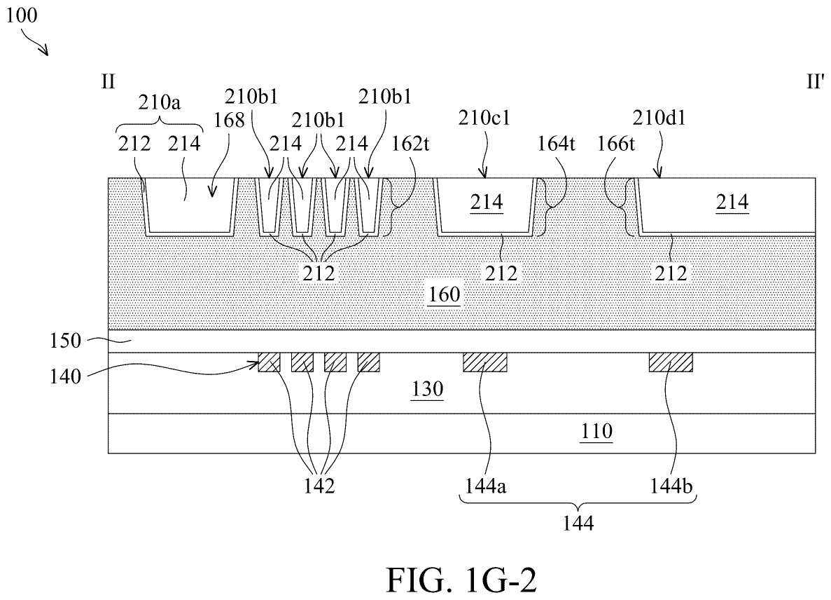

FIGS. 1A-1G are cross-sectional views of various stages of a process for forming a semiconductor device structure, in accordance with some embodiments. FIG. 1A-1 is a top view of the semiconductor device structure of FIG. 1A, in accordance with some embodiments. FIG. 1A is a cross-sectional view illustrating the semiconductor device structure along a sectional line I-I′ in FIG. 1A-1, in accordance with some embodiments.

As shown in FIGS. 1A and 1A-1, a substrate 110 is provided, in accordance with some embodiments. The substrate 110 includes, for example, a semiconductor substrate. The substrate 110 includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof.

The substrate 110 may also include multi-layer semiconductors, semiconductor on insulator (SOI) (such as silicon on insulator or germanium on insulator), or a combination thereof.

In some embodiments, various device elements 120 are formed in and/or over the substrate 110. Examples of the various device elements 120 include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements 120. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements 120 formed in and/or over the substrate 110 in the active regions. In some embodiments, the isolation features include shallow trench isolation (STI) features, local oxidation of silicon (LOCOS) features, other suitable isolation features, or a combination thereof.

As shown in FIGS. 1A and 1A-1, a dielectric layer 130 and an interconnect structure are formed over the substrate 110, in accordance with some embodiments. The interconnect structure is formed in the dielectric layer 130, in accordance with some embodiments.

The interconnect structure includes wiring layers (including the wiring layer 140) and conductive vias (not shown), in accordance with some embodiments. The conductive vias are connected between the wiring layers and between the wiring layers and the device elements 120 formed in and/or over the substrate 110, in accordance with some embodiments.

Each wiring layer includes conductive lines, in accordance with some embodiments. For example, the wiring layer 140 includes conductive lines 142 and 144, in accordance with some embodiments. The average line width of the conductive lines 142 is less than the average line width of the conductive lines 144, in accordance with some embodiments. The distance D142 between the conductive lines 142 is less than the distance D144 between the conductive lines 144, in accordance with some embodiments.

The dielectric layer 130 is made of silicon oxide, silicon oxynitride, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments.

The dielectric layer 130 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process.

The interconnect structure is made of conductive materials such as metal (e.g., aluminum, copper or tungsten) or alloys thereof, in accordance with some embodiments.

As shown in FIGS. 1A and 1A-1, an etch stop layer 150 is formed over the dielectric layer 130 and the wiring layer 140, in accordance with some embodiments. The etch stop layer 150, the dielectric layer 130, and the wiring layer 140 are made of different materials, in accordance with some embodiments. The etch stop layer 150 is made of an insulating material such as tetraethoxysilane (TEOS) and/or silicon carbide (SiC), in accordance with some embodiments.

The etch stop layer 150 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process.

As shown in FIGS. 1A and 1A-1, a dielectric layer 160 is formed over the etch stop layer 150, in accordance with some embodiments. The dielectric layer 160 and the etch stop layer 150 are made of different materials, in accordance with some embodiments.

The dielectric layer 160 is made of silicon oxide, silicon oxynitride, borosilicate glass (BSG), phosphoric silicate glass (PSG), borophosphosilicate glass (BPSG), fluorinated silicate glass (FSG), a low-k material, a porous dielectric material, or a combination thereof, in accordance with some embodiments.

The dielectric layer 160 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process.

As shown in FIGS. 1A and 1A-1, an etch stop layer 170 is formed over the dielectric layer 160, in accordance with some embodiments. The etch stop layer 170 is also referred to as an antireflection coating (ARC) layer, in accordance with some embodiments.

The etch stop layer 170 and the dielectric layer 160 are made of different materials, in accordance with some embodiments. The etch stop layer 170 is made of an insulating material such as a polymer material, in accordance with some embodiments. The etch stop layer 170 is formed using a spin-on process or another suitable process.

As shown in FIGS. 1A and 1A-1, an etch stop layer 180 is formed over the etch stop layer 170, in accordance with some embodiments. The etch stop layers 170 and 180 are made of different materials, in accordance with some embodiments. The etch stop layer 180 is made of an etch resistance material such as a nitride material (e.g., TiN), in accordance with some embodiments.

The etch stop layer 180 is formed using a chemical vapor deposition (CVD) process, such as a low-pressure CVD process, a plasma-enhanced CVD process, or a high-density plasma CVD process, an atomic layer deposition process, a physical vapor deposition process, or another suitable process.

As shown in FIGS. 1A and 1A-1, a protection layer 190 is formed over the etch stop layer 180, in accordance with some embodiments. The protection layer 190 is used to protect the etch stop layer 180 from oxidation, in accordance with some embodiments.

The protection layer 190 and the etch stop layer 180 are made of different materials, in accordance with some embodiments. The protection layer 190 is made of an insulating material such as a polymer material, in accordance with some embodiments. The protection layer 190 is formed using a spin-on process or another suitable process.

FIG. 1B-1 is a top view of the semiconductor device structure of FIG. 1B, in accordance with some embodiments. FIG. 1B is a cross-sectional view illustrating the semiconductor device structure along a sectional line I-I′ in FIG. 1B-1, in accordance with some embodiments.

As shown in FIGS. 1B and 1B-1, portions of the protection layer 190 and the etch stop layer 180 are removed to form trenches TR1, TR2 and TR3 in the protection layer 190 and the etch stop layer 180, in accordance with some embodiments.

The trenches TR1, TR2 and TR3 pass through the protection layer 190, in accordance with some embodiments. The trenches TR1, TR2 and TR3 expose portions of the etch stop layer 180, in accordance with some embodiments. The trenches TR1, TR2 and TR3 extend into the etch stop layer 180, in accordance with some embodiments.

The trenches TR1, TR2 and TR3 do not pass through the etch stop layer 180, in accordance with some embodiments. The trench TR2 is narrower than the trench TR1, in accordance with some embodiments. The trench TR2 is narrower than the trench TR3, in accordance with some embodiments. The removal process include a photolithography process and an etching process, in accordance with some embodiments.

FIG. 1C-1 is a top view of the semiconductor device structure of FIG. 1C, in accordance with some embodiments. FIG. 1C is a cross-sectional view illustrating the semiconductor device structure along a sectional line I-I′ in FIG. 1C-1, in accordance with some embodiments.

As shown in FIGS. 1C and 1C-1, portions of the protection layer 190 and the etch stop layers 170 and 180 are removed to form trenches TR4 and TR5 in the protection layer 190 and the etch stop layers 170 and 180, in accordance with some embodiments.

The trenches TR4 and TR5 pass through the protection layer 190 and the etch stop layer 180, in accordance with some embodiments. The trenches TR4 and TR5 expose portions of the etch stop layer 170, in accordance with some embodiments. The trenches TR4 and TR5 extend into the etch stop layer 170, in accordance with some embodiments. The trenches TR4 and TR5 do not pass through the etch stop layer 170, in accordance with some embodiments.

The trench TR4 is narrower than the trench TR5, in accordance with some embodiments. The trench TR4 is narrower than the trench TR3, in accordance with some embodiments. The trench TR4 is narrower than the trench TR1, in accordance with some embodiments. The distance D1 between the trenches TR2 and TR4 is less than the distance D2 between the trenches TR3 and TR5, in accordance with some embodiments.

The removal process also removes portions of the etch stop layers 170 and 180 under the trenches TR1, TR2 and TR3, and therefore the trenches TR1, TR2 and TR3 pass through the etch stop layer 180 and extend into the etch stop layer 170 after the removal process is performed, in accordance with some embodiments.

The trenches TR1, TR2 and TR3 do not pass through the etch stop layer 170, in accordance with some embodiments. The removal process include a photolithography process and an etching process, in accordance with some embodiments.

FIG. 1D-1 is a top view of the semiconductor device structure of FIG. 1D, in accordance with some embodiments. FIG. 1D is a cross-sectional view illustrating the semiconductor device structure along a sectional line I-I′ in FIG. 1D-1, in accordance with some embodiments.

As shown in FIGS. 1D and 1D-1, portions of the dielectric layer 160 and the etch stop layer 170 under the trenches TR2, TR4, TR5, and TR3 are removed to form via holes 162v, 164v and 166v in the dielectric layer 160, in accordance with some embodiments.

The via holes 162v do not pass through the dielectric layer 160, in accordance with some embodiments. The via holes 164v and 166v do not pass through the dielectric layer 160, in accordance with some embodiments. The via hole 162v is narrower than the via hole 164v, in accordance with some embodiments. The via hole 162v is narrower than the via hole 166v, in accordance with some embodiments. As shown in FIG. 1D-1, the via holes 162v have an oval shape, in accordance with some embodiments.

FIG. 1E-1 is a top view of the semiconductor device structure of FIG. 1E, in accordance with some embodiments. FIG. 1E is a cross-sectional view illustrating the semiconductor device structure along a sectional line I-I′ in FIG. 1E-1, in accordance with some embodiments.

As shown in FIGS. 1E and 1E-1, an etching process is performed to remove the protection layer 190 and portions of the etch stop layer 170 and the dielectric layer 160 under the trenches TR1, TR2, TR3, TR4 and TR5, in accordance with some embodiments.

After the removal process, trenches 168, 162t, 164t, and 166t are formed in the dielectric layer 160 under the trenches TR1, TR2, TR4, TR5 and TR3, in accordance with some embodiments. The dielectric layer 160 originally under the via holes 162v is thinned by the removal process, in accordance with some embodiments. The via holes 162v do not pass through the dielectric layer 160 after the removal process, in accordance with some embodiments.

The holes 162v are under and connected to the corresponding trenches 162t, in accordance with some embodiments. The holes 162v extend toward the corresponding lower conductive lines 142, in accordance with some embodiments.

The dielectric layer 160 originally under the via holes 164v and 166v is removed by the removal process, in accordance with some embodiments. The via holes 164v and 166v pass through the dielectric layer 160 after the removal process, in accordance with some embodiments.

The trenches TR2 and TR4 are narrower than the trenches TR3 and TR5 and the distance D1 between the trenches TR2 and TR4 is less than the distance D2 between the trenches TR3 and TR5, in accordance with some embodiments. That is, the pattern density of the trenches TR2 and TR4 is greater than the pattern density of the trenches TR3 and TR5, in accordance with some embodiments.

Therefore, the etching rate of the dielectric layer 160 under the trenches TR2 and TR4 is less than that of the dielectric layer 160 under the trenches TR3 and TR5 due to the loading effect, in accordance with some embodiments. As a result, the via holes 162v do not pass through the dielectric layer 160, and the via holes 164v and 166v pass through the dielectric layer 160 after the removal process, in accordance with some embodiments.

Thereafter, as shown in FIGS. 1E and 1E-1, portions of the etch stop layer 150 and the dielectric layer 130 under the via holes 164v and 166v are removed to form openings 152 and 154 in the etch stop layer 150 and recesses 132a and 132b in the dielectric layer 130, in accordance with some embodiments.

The conductive lines 144 include conductive lines 144a and 144b, in accordance with some embodiments. The openings 152 and 154 expose portions of the conductive lines 144a and 144b respectively, in accordance with some embodiments. The via holes 164v and 166v expose the portions of the conductive lines 144a and 144b respectively, in accordance with some embodiments.

Specifically, the via hole 164v and the opening 152 extend across the conductive line 144a, in accordance with some embodiments. The via hole 164v and the opening 152 expose opposite sidewalls S1 and S2 of the conductive line 144a, in accordance with some embodiments.

The via hole 166v and the opening 154 do not extend across the conductive line 144b, in accordance with some embodiments. The via hole 166v and the opening 154 expose the sidewall S2′ of the conductive line 144b, in accordance with some embodiments. The dielectric layer 160 and the etch stop layer 150 cover the sidewall S1′ of the conductive line 144b, in accordance with some embodiments.

As shown in FIG. 1F, a seed layer 212 is formed over the dielectric layer 160, the etch stop layer 150, the wiring layer 140, and the dielectric layer 130, in accordance with some embodiments. The seed layer 212 conformally covers the dielectric layer 160, the etch stop layer 150, the wiring layer 140, and the dielectric layer 130, in accordance with some embodiments.

The seed layer 212 conformally covers the top surface B1 and the sidewalls S1 and S2 of the conductive line 144a, in accordance with some embodiments. The seed layer 212 is in contact with the top surface B1 and the sidewalls S1 and S2 of the conductive line 144a, in accordance with some embodiments.

The seed layer 212 conformally covers the top surface B2 and the sidewall S2′ of the conductive line 144b, in accordance with some embodiments. The seed layer 212 is in contact with the top surface B2 and the sidewall S2′ of the conductive line 144b, in accordance with some embodiments. The seed layer 212 is spaced apart from the sidewall S1′ of the conductive line 144b, in accordance with some embodiments.

The seed layer 212 is made of a conductive material, such as metal (e.g., copper, aluminum, gold, silver, or tungsten) or alloys thereof, in accordance with some embodiments. The seed layer 212 is formed using a deposition process, such as a physical vapor deposition process or a chemical vapor deposition process, in accordance with some embodiments.

As shown in FIG. 1F, a conductive layer 214 is formed over the seed layer 212 and in the trenches 168, 162t, 164t, and 166t and the via holes 162v, 164v and 166v, in accordance with some embodiments.

The conductive layer 214 is made of a conductive material, such as metal (e.g., copper, aluminum, gold, silver, or tungsten) or alloys thereof, in accordance with some embodiments. The conductive layer 214 is formed using a plating process, such as an electroplating process, in accordance with some embodiments.

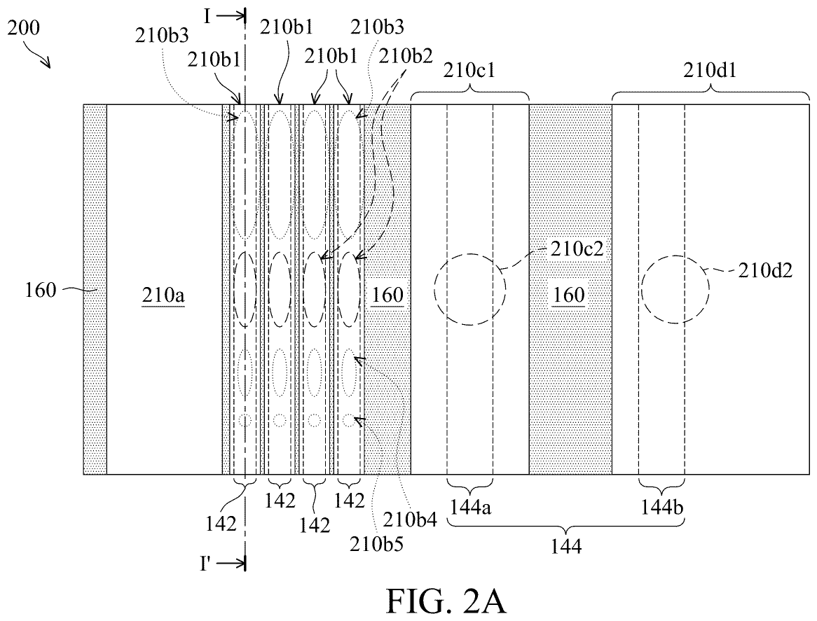

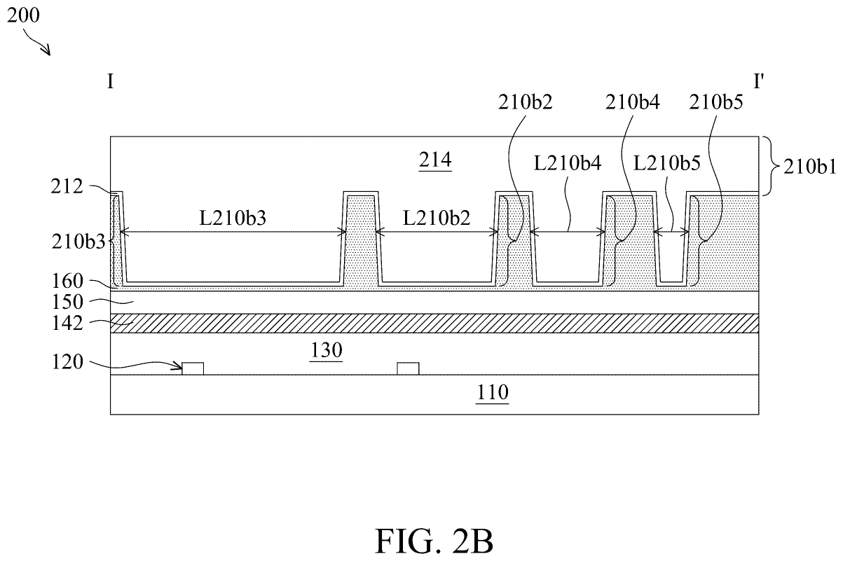

FIG. 1G-1 is a top view of the semiconductor device structure of FIG. 1G, in accordance with some embodiments. FIG. 1G is a cross-sectional view illustrating the semiconductor device structure along a sectional line I-I′ in FIG. 1G-1, in accordance with some embodiments. FIG. 1G-2 is a cross-sectional view illustrating the semiconductor device structure along a sectional line II-II′ in FIG. 1G-1, in accordance with some embodiments.

As shown in FIGS. 1G, 1G-1 and 1G-2, portions of the seed layer 212 and the conductive layer 214 outside of the trenches 168, 162t, 164t, and 166t and the via holes 162v, 164v and 166v are removed, in accordance with some embodiments. After the removal process, portions of the seed layer 212 and the conductive layer 214 remaining in the trench 168 together form a conductive line 210a, in accordance with some embodiments. The linewidth W210a of the upper conductive line 210a ranges from about 180 nm to about 360 nm, in accordance with some embodiments.

The portions of the seed layer 212 and the conductive layer 214 remaining in the trenches 162t together form conductive lines 210b1, in accordance with some embodiments. The linewidth W210b1 of the conductive lines 210b1 ranges from about 75 nm to about 150 nm, in accordance with some embodiments.

The height H210b1 of the conductive lines 210b1 ranges from about 150 nm to about 200 nm, in accordance with some embodiments. The ratio of the height H210b1 to the linewidth W210b1 ranges from about 1 to about 3, in accordance with some embodiments.

The distance D210b1 between the conductive lines 210b1 ranges from about 38 nm to about 76 nm, in accordance with some embodiments. The distance between top portions of the conductive lines 210b1 ranges from about 38 nm to about 45 nm, in accordance with some embodiments. The distance between bottom portions of the conductive lines 210b1 ranges from about 70 nm to about 76 nm, in accordance with some embodiments.

The portions of the seed layer 212 and the conductive layer 214 remaining in the via holes 162v together form capacitor via structures 210b2, in accordance with some embodiments. The capacitor via structures 210b2 extend toward the corresponding lower conductive lines 142, in accordance with some embodiments.

The width W210b2 of the capacitor via structures 210b2 ranges from about 50 nm to about 100 nm, in accordance with some embodiments. The height H210b2 of the capacitor via structures 210b2 ranges from about 200 nm to about 250 nm, in accordance with some embodiments.

The ratio of the height H210b2 to the width W210b2 ranges from about 2 to about 5, in accordance with some embodiments. The distance D210b2 between the capacitor via structures 210b2 ranges from about 50 nm to about 90 nm, in accordance with some embodiments.

The dielectric layer 160 and the etch stop layer 150 separate the capacitor via structures 210b2 from the lower conductive lines 142, in accordance with some embodiments. The capacitor via structures 210b2 are over and electrically insulated from the lower conductive lines 142, in accordance with some embodiments.

The linewidth W210b1 of the upper conductive lines 210b1 is less than the linewidth W210a of the upper conductive line 210a, in accordance with some embodiments. The ratio of the linewidth W210b1 to the linewidth W210a ranges from about 0.2 to about 0.9, in accordance with some embodiments.

As shown in FIG. 1G-1, the distance D210bl between the upper conductive lines 210b1 is less than the distance D210cd1 between the upper conductive lines 210cl and 210d1, in accordance with some embodiments. The ratio of the distance D210b1 to the distance D210cd1 ranges from about 0.1 to about 0.4, in accordance with some embodiments.

As shown in FIG. 1G, the portions of the seed layer 212 and the conductive layer 214 remaining in the trenches 164t together form a conductive line 210c1, in accordance with some embodiments. The portions of the seed layer 212 and the conductive layer 214 remaining in the via hole 164v together form a conductive via structure 210c2, in accordance with some embodiments. The conductive via structure 210c2 is connected to the conductive line 144 thereunder, in accordance with some embodiments.

The portions of the seed layer 212 and the conductive layer 214 remaining in the trenches 166t together form a conductive line 210d1, in accordance with some embodiments. The portions of the seed layer 212 and the conductive layer 214 remaining in the via hole 166v together form a conductive via structure 210d2, in accordance with some embodiments. The conductive via structure 210d2 is connected to the conductive line 144 thereunder, in accordance with some embodiments.

The removal process includes a planarization process such as a chemical mechanical polishing process, in accordance with some embodiments. In this step, a semiconductor device structure 100 is substantially formed, in accordance with some embodiments.

As shown in FIG. 1G-1, the distance D210b2 between the capacitor via structures 210b2 is less than the distance D210cd2 between the conductive via structures 210c2 and 210d2, in accordance with some embodiments. The distance D210b2 ranges from about 16 nm to about 32 nm, in accordance with some embodiments.

The extending direction X142 of the lower conductive lines 142 is substantially parallel to the extending direction X210b1 of the upper conductive lines 210b1, in accordance with some embodiments. The extending direction X210b1 is substantially parallel to the extending direction X210cl of the upper conductive line 210cl, in accordance with some embodiments.

The capacitor via structures 210b2 have an oval shape, in accordance with some embodiments. The length L210b2 of the capacitor via structure 210b2 is greater than the width W210b2 of the capacitor via structure 210b2, in accordance with some embodiments. The ratio of the length L210b2 to the width W210b2 ranges from about 1.5 to about 4, in accordance with some embodiments.

The capacitor via structures 210b2 have the same length direction X210b2, in accordance with some embodiments. The length direction X210b2 is also referred to as a longitudinal axis, in accordance with some embodiments. The lower conductive lines 142 have the same extending direction X142, in accordance with some embodiments. The length direction X210b2 of the capacitor via structures 210b2 is substantially parallel to the extending direction X142 of the lower conductive lines 142, in accordance with some embodiments.

The upper conductive lines 210b1 have the same extending direction X210b1, in accordance with some embodiments. The length direction X210b2 of the capacitor via structures 210b2 is substantially parallel to the extending direction X210b1 of the upper conductive lines 210b1, in accordance with some embodiments.

The extending direction X210b1 of the upper conductive lines 210b1 is substantially parallel to the extending direction X142 of the lower conductive lines 142, in accordance with some embodiments. The capacitor via structures 210b2 are adjacent to and spaced apart from each other, in accordance with some embodiments. The capacitor via structures 210b2 are electrically insulated from each other, in accordance with some embodiments.

As shown in FIG. 1G, the dielectric layer 160 covers an end surface E1 of the capacitor via structure 210b2, in accordance with some embodiments. The end surface E1 faces away from the upper conductive line 210b1 thereover, in accordance with some embodiments. The distance D3 between the end surface E1 of the capacitor via structure 210b2 and the lower conductive line 142 ranges from about 20 nm to about 100 nm, in accordance with some embodiments.

The upper conductive lines 210b1 include lines A1, A2, A3, and A4, in accordance with some embodiments. The lower conductive lines 142 include lines 142a, 142b, 142c, and 142d, in accordance with some embodiments. The lines A1, A3, 142b and 142d are applied with a low voltage, and the lines A2, A4, 142a and 142c are applied with a high voltage, in accordance with some embodiments. The low voltage is lower than the high voltage, in accordance with some embodiments. The difference between the high voltage and the low voltage ranges from about 1V to about 20V, in accordance with some embodiments.

The formation of the capacitor via structures 210b2 can additionally create vertical capacitors each includes one of the capacitor via structures 210b2 and the corresponding one of the lower conductive lines 142, and can additionally create lateral capacitors each includes adjacent two of the capacitor via structures 210b2, in accordance with some embodiments.

Since the capacitor via structures 210b2 are close to the lower conductive lines 142, the capacitance of the vertical capacitors is increased, in accordance with some embodiments. Since the capacitor via structures 210b2 are close to each other, the capacitance of the lateral capacitors is increased, in accordance with some embodiments.

As shown in FIG. 1G-1, since the length L210b2 of the capacitor via structure 210b2 is increased, the area of the lateral capacitors is increased, which increases the capacitance of the lateral capacitors, in accordance with some embodiments.

Since the area of the lateral capacitor between adjacent two capacitor via structures 210b2 is greater than the area of the vertical capacitor between the capacitor via structure 210b2 and the lower conductive line 142 thereunder, the lateral capacitor is greater than the vertical capacitor, in accordance with some embodiments. The ratio of the capacitance of the lateral capacitor to that of the vertical capacitor ranges from about 3 to about 5, in accordance with some embodiments.

FIG. 2A is a top view of a semiconductor device structure 200, in accordance with some embodiments. FIG. 2B is a cross-sectional view illustrating the semiconductor device structure along a sectional line I-I′ in FIG. 2A, in accordance with some embodiments.

As shown in FIGS. 2A and 2B, the semiconductor device structure 200 is similar to the semiconductor device structure 100 of FIG. 1G-1, except that the semiconductor device structure 200 further includes capacitor via structures 210b3, 210b4, and 210b5, in accordance with some embodiments. As shown in FIG. 2B, the capacitor via structures 210b3, 210b4, and 210b5 are under and connected to the corresponding conductive line 210b1, in accordance with some embodiments.

The length L210b3 of the capacitor via structure 210b3 is greater than the length L210b2 of the capacitor via structure 210b2, in accordance with some embodiments. The length L210b2 of the capacitor via structure 210b2 is greater than the length L210b4 of the capacitor via structure 210b4, in accordance with some embodiments. The length L210b4 of the capacitor via structure 210b4 is greater than the length L210b5 of the capacitor via structure 210b5, in accordance with some embodiments.

As shown in FIG. 2A, the capacitor via structures 210b2, 210b3, and 210b4 have an oval shape, in accordance with some embodiments. As shown in FIG. 2A, the capacitor via structures 210b5 have a round shape, in accordance with some embodiments.

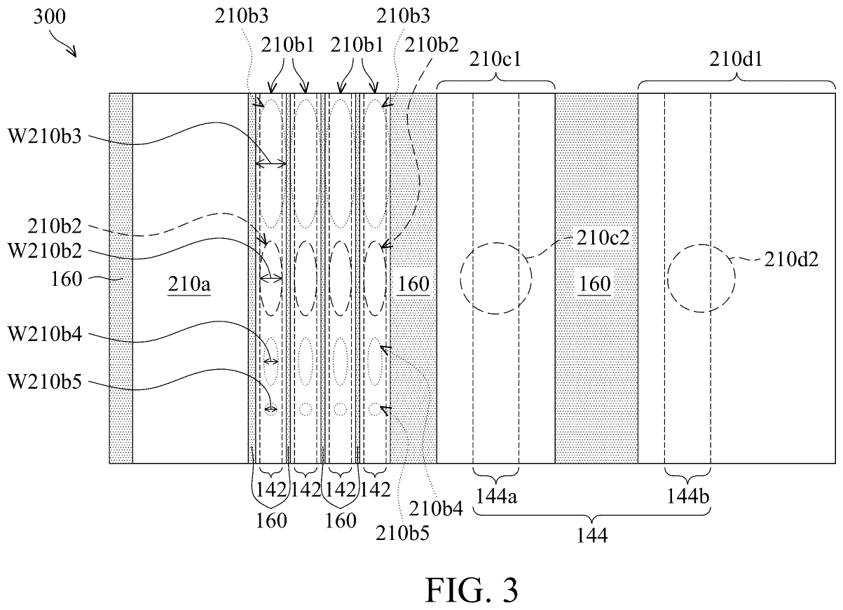

FIG. 3 is a top view of a semiconductor device structure 300, in accordance with some embodiments. As shown in FIG. 3, the semiconductor device structure 300 is similar to the semiconductor device structure 200 of FIG. 2A, except that the capacitor via structures 210b2, 210b3, 210b4, and 210b5 of the semiconductor device structure 300 have different widths, in accordance with some embodiments.

The width W210b3 of the capacitor via structure 210b3 is greater than the width W210b2 of the capacitor via structure 210b2, in accordance with some embodiments. The width W210b2 of the capacitor via structure 210b2 is greater than the width W210b4 of the capacitor via structure 210b4, in accordance with some embodiments. The width W210b4 of the capacitor via structure 210b4 is greater than the width W210b5 of the capacitor via structure 210b5, in accordance with some embodiments.

Processes and materials for forming the semiconductor device structures 200 and 300 may be similar to, or the same as, those for forming the semiconductor device structure 100 described above. Elements designated by the same or similar reference numbers as those in FIGS. 1A to 3 have the same or similar structures and the materials. Therefore, the detailed descriptions thereof will not be repeated herein.

In accordance with some embodiments, semiconductor device structures and methods for forming the same are provided. The methods (for forming the semiconductor device structure) form a capacitor via structure, an upper conductive line, and a lower conductive line. The capacitor via structure is between the upper conductive line and the lower conductive line. The capacitor via structure is connected to the upper conductive line and spaced apart from the lower conductive line. The capacitor via structure and the lower conductive line together form a capacitor. Since the capacitor via structure is close to the lower conductive line, the capacitance of the capacitor is increased.

In accordance with some embodiments, a method for forming a semiconductor device structure is provided. The method includes forming a first lower conductive line over a substrate. The method includes forming a dielectric layer over the substrate and the first lower conductive line. The method includes partially removing the dielectric layer to form a first trench, a second trench and a first hole in the dielectric layer. The first hole is under and connected to the first trench, and the first hole extends toward the first lower conductive line. The method includes forming a first upper conductive line, a second upper conductive line, and a first capacitor via structure in the first trench, the second trench and the first hole respectively. A first linewidth of the first upper conductive line is less than a second linewidth of the second upper conductive line, and the first capacitor via structure is over and electrically insulated from the first lower conductive line.

In accordance with some embodiments, a method for forming a semiconductor device structure is provided. The method includes forming a dielectric layer over a substrate. The method includes partially removing the dielectric layer to form a first trench, a second trench, a first hole and a second hole in the dielectric layer. The first hole is under and connected to the first trench, and the second hole is under and connected to the second trench. The method includes forming a first upper conductive line, a second upper conductive line, a first capacitor via structure and a second capacitor via structure in the first trench, the second trench, the first hole, and the second hole respectively. A first extending direction of the first upper conductive line is substantially parallel to a second extending direction of the second upper conductive line in a top view of the first upper conductive line and the second upper conductive line, the first capacitor via structure is adjacent to and spaced apart from the second capacitor via structure, the dielectric layer covers a first end surface of the first capacitor via structure and a second end surface of the second capacitor via structure, the first end surface faces away from the first upper conductive line, and the second end surface faces away from the second upper conductive line.

In accordance with some embodiments, a semiconductor device structure is provided. The semiconductor device structure includes a substrate. The semiconductor device structure includes a first lower conductive line over the substrate. The semiconductor device structure includes a dielectric layer over the substrate and the first lower conductive line. The semiconductor device structure includes a first upper conductive line embedded in the dielectric layer. The semiconductor device structure includes a first capacitor via structure in the dielectric layer and under and connected to the first upper conductive line. The first capacitor via structure extends toward and is electrically insulated from the first lower conductive line. The semiconductor device structure includes a second upper conductive line embedded in the dielectric layer. A first linewidth of the first upper conductive line is less than a second linewidth of the second upper conductive line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a first lower conductive line over a substrate;
forming a dielectric layer over the substrate and the first lower conductive line;
partially removing the dielectric layer to form a first trench, a second trench and a first hole in the dielectric layer, wherein the first hole is under and connected to the first trench, and the first hole extends toward the first lower conductive line; and
forming a first upper conductive line, a second upper conductive line, and a first capacitor via structure in the first trench, the second trench and the first hole respectively, wherein a first linewidth of the first upper conductive line is less than a second linewidth of the second upper conductive line, and the first capacitor via structure is over and electrically insulated from the first lower conductive line.

2. The method for forming the semiconductor device structure as claimed in claim 1, wherein a first extending direction of the first lower conductive line is substantially parallel to a second extending direction of the first upper conductive line in a top view of the first lower conductive line and the first upper conductive line.

3. The method for forming the semiconductor device structure as claimed in claim 1, wherein the first capacitor via structure has an oval shape or a round shape.

4. The method for forming the semiconductor device structure as claimed in claim 1, wherein a length of the first capacitor via structure is greater than a width of the first capacitor via structure in a top view of the first capacitor via structure.

5. The method for forming the semiconductor device structure as claimed in claim 4, wherein a length direction of the first capacitor via structure is substantially parallel to a first extending direction of the first lower conductive line in a top view of the first capacitor via structure, the first lower conductive line and the first upper conductive line.

6. The method for forming the semiconductor device structure as claimed in claim 5, wherein the length direction of the first capacitor via structure is substantially parallel to a second extending direction of the first upper conductive line in the top view.

7. The method for forming the semiconductor device structure as claimed in claim 1, further comprising:
forming a second lower conductive line over the substrate, wherein the partially removing of the dielectric layer further forms a third trench and a second hole in the dielectric layer, the second hole is under and connected to the third trench, and the second hole extends toward the second lower conductive line; and
forming a third upper conductive line and a second capacitor via structure in the third trench and the second hole respectively, wherein a third linewidth of the third upper conductive line is less than the second linewidth of the second upper conductive line, the second capacitor via structure is over and electrically insulated from the second lower conductive line, and the first capacitor via structure is adjacent to and spaced apart from the second capacitor via structure.

8. The method for forming the semiconductor device structure as claimed in claim 7, wherein a first length of the second capacitor via structure is greater than a first width of the second capacitor via structure, and a first length direction of the second capacitor via structure is substantially parallel to a first extending direction of the second lower conductive line in a top view of the second capacitor via structure and the second lower conductive line.

9. The method for forming the semiconductor device structure as claimed in claim 8, wherein the first length direction of the second capacitor via structure is substantially parallel to a second extending direction of the third upper conductive line.

10. The method for forming the semiconductor device structure as claimed in claim 8, wherein a second length of the first capacitor via structure is greater than a second width of the first capacitor via structure, and the first length direction of the second capacitor via structure is substantially parallel to a second length direction of the first capacitor via structure in a top view of the first capacitor via structure and the second capacitor via structure.

11. A method for forming a semiconductor device structure, comprising:
forming a dielectric layer over a substrate;
partially removing the dielectric layer to form a first trench, a second trench, a first hole and a second hole in the dielectric layer, wherein the first hole is under and connected to the first trench, and the second hole is under and connected to the second trench; and
forming a first upper conductive line, a second upper conductive line, a first capacitor via structure and a second capacitor via structure in the first trench, the second trench, the first hole, and the second hole respectively, wherein
a first extending direction of the first upper conductive line is substantially parallel to a second extending direction of the second upper conductive line in a top view of the first upper conductive line and the second upper conductive line, the first capacitor via structure is adjacent to and spaced apart from the second capacitor via structure, the dielectric layer covers a first end surface of the first capacitor via structure and a second end surface of the second capacitor via structure, the first end surface faces away from the first upper conductive line, and the second end surface faces away from the second upper conductive line.

12. The method for forming the semiconductor device structure as claimed in claim 11, wherein the first capacitor via structure is electrically insulated from the second capacitor via structure.

13. The method for forming the semiconductor device structure as claimed in claim 11, wherein a first longitudinal axis of the first capacitor via structure is substantially parallel to a second longitudinal axis of the second capacitor via structure in a top view of the first capacitor via structure and the second capacitor via structure.

14. The method for forming the semiconductor device structure as claimed in claim 11, further comprising:
forming a first lower conductive line and a second lower conductive line over the substrate, wherein the dielectric layer covers the first lower conductive line and the second lower conductive line, the first capacitor via structure extends toward and is electrically insulated from the first lower conductive line, and the second capacitor via structure extends toward and is electrically insulated from the second lower conductive line.

15. The method for forming the semiconductor device structure as claimed in claim 14, wherein the first extending direction of the first upper conductive line is substantially parallel to a third extending direction of the first lower conductive line.

16. A semiconductor device structure, comprising:
a substrate;
a first lower conductive line over the substrate;
a dielectric layer over the substrate and the first lower conductive line;
a first upper conductive line embedded in the dielectric layer;
a first capacitor via structure in the dielectric layer and under and connected to the first upper conductive line, wherein the first capacitor via structure extends toward and is electrically insulated from the first lower conductive line; and
a second upper conductive line embedded in the dielectric layer, wherein a first linewidth of the first upper conductive line is less than a second linewidth of the second upper conductive line.

17. The semiconductor device structure as claimed in claim 16, wherein a longitudinal axis of the first capacitor via structure is substantially parallel to a first extending direction of the first lower conductive line.

18. The semiconductor device structure as claimed in claim 17, wherein the longitudinal axis of the first capacitor via structure is substantially parallel to a second extending direction of the first upper conductive line.

19. The semiconductor device structure as claimed in claim 16, further comprising:
a second lower conductive line over the substrate, wherein the dielectric layer covers the second lower conductive line;
a third upper conductive line embedded in the dielectric layer;
a second capacitor via structure in the dielectric layer and under and connected to the third upper conductive line, wherein the second capacitor via structure extends toward and is electrically insulated from the second lower conductive line.

20. The semiconductor device structure as claimed in claim 19, wherein a first longitudinal axis of the first capacitor via structure is substantially parallel to a second longitudinal axis of the second capacitor via structure in a top view of the first capacitor via structure and the second capacitor via structure.
